(19) United States
(12) Patent Application Publication
(10) Pub. No.: US 2022/0381520 A1
(43) Pub. Date: Dec. 1, 2022

(54) HEAT DISSIPATING DEVICE

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(73) Assignees: Inventec (Pudong) Technology Corp., Shanghai (CN); Inventec Corporation, Taipei (TW)

(21) Appl. No.: 17/349,867

(22) Filed: Jun. 16, 2021

(30) Foreign Application Priority Data
May 26, 2021 (CN) 202110575251.2

(51) Int. Cl. F28D 15/02; F28D 15/04; F28F 1/16; H05K 7/20

(52) U.S. Cl. CPC F28D 15/0233; F28D 15/0266; F28D 15/04; F28F 1/16; F28D 15/0275; H05K 7/2029

(57) ABSTRACT

A heat dissipating device includes a thermosyphon, a first liquid cooling tube and a first heat dissipating fin set. The thermosyphon has an evaporation portion and a condensation portion. The first liquid cooling tube is sleeved on the condensation portion. The first heat dissipating fin set is sleeved on the first liquid cooling tube.

### BACKGROUND OF THE INVENTION

### 1. Field of the Invention

The invention relates to a heat dissipating device and, more particularly, to a heat dissipating device capable of effectively improving heat dissipating efficiency.

### 2. Description of the Prior Art

Since the structure of a thermosyphon is simple, the thermosyphon is usually used to dissipate heat from an electronic component. In general, an evaporation portion of the thermosyphon is in contact with an electronic component (e.g. central processing unit or graphics card) that generates more heat for purpose of heat dissipation. However, the heat of other electronic components (e.g. memories) which are not in contact with the thermosyphon cannot be dissipated. Thus, the heat of other electronic components has to be dissipated by the air inside the chassis. Then, the heated air will flow out of the chassis and then be exhausted out of a machine room through an air conditioner. During the aforesaid process, the hot air will mix with the cold air before being cooled, such that the temperature of the inlet air of the chassis will rise and the heat dissipating efficiency will be reduced.

### SUMMARY OF THE INVENTION

The invention provides a heat dissipating device capable of effectively improving heat dissipating efficiency, so as to solve the aforesaid problems.

According to an embodiment of the invention, a heat dissipating device comprises a thermosyphon, a first liquid cooling tube and a first heat dissipating fin set. The thermosyphon has an evaporation portion and a condensation portion. The first liquid cooling tube is sleeved on the condensation portion. The first heat dissipating fin set is sleeved on the first liquid cooling tube.

In another embodiment, the heat dissipating device further comprises a second liquid cooling tube and a second heat dissipating fin set. The second liquid cooling tube and the first liquid cooling tube are connected in parallel. The second heat dissipating fin set is sleeved on the second liquid cooling tube.

According to an embodiment of the invention, a heat dissipating device comprises a thermosyphon, a first liquid cooling tube, a second liquid cooling tube and a heat dissipating fin set. The thermosyphon has an evaporation portion and a condensation portion. The first liquid cooling tube is sleeved on the condensation portion. The second liquid cooling tube and the first liquid cooling tube are connected in parallel. The heat dissipating fin set is sleeved on the second liquid cooling tube.

As mentioned in the above, the invention may sleeve the first liquid cooling tube on the condensation portion of the thermosyphon and sleeve the first heat dissipating fin set on the first liquid cooling tube. The evaporation portion of the thermosyphon is in contact with an electronic component. The heat generated by the electronic component evaporates a cooling liquid within the thermosyphon. Then, the vapor flows to the condensation portion and then is cooled by the first liquid cooling tube. At the same time, the first heat dissipating fin set absorbs the heat inside the chassis and then performs heat exchange with the first liquid cooling tube, such that the air will be cooled before flowing out of the chassis. Accordingly, the heat dissipating efficiency of the heat dissipating device can be effectively improved. Furthermore, the invention may add the second liquid cooling tube and the second heat dissipating fin set to further improve the heat exchange efficiency. In another embodiment, the invention may utilize the first liquid cooling tube to cool the condensation portion of the thermosyphon and utilize the second liquid cooling tube and the heat dissipating fin set thereon to perform heat exchange for the hot air inside the chassis. In other words, when the second liquid cooling tube and the first liquid cooling tube are connected in parallel, there may be no heat dissipating fin set disposed on the first liquid cooling tube and it depends on practical applications.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a heat dissipating device according to an embodiment of the invention.

FIG. 2 is an exploded view illustrating the heat dissipating device shown in FIG. 1.

FIG. 3 is a perspective view illustrating a heat dissipating device according to another embodiment of the invention.

FIG. 4 is an exploded view illustrating the heat dissipating device shown in FIG. 3.

FIG. 5 is a perspective view illustrating a heat dissipating device according to another embodiment of the invention.

FIG. 6 is a perspective view illustrating a heat dissipating device according to another embodiment of the invention.

### DETAILED DESCRIPTION

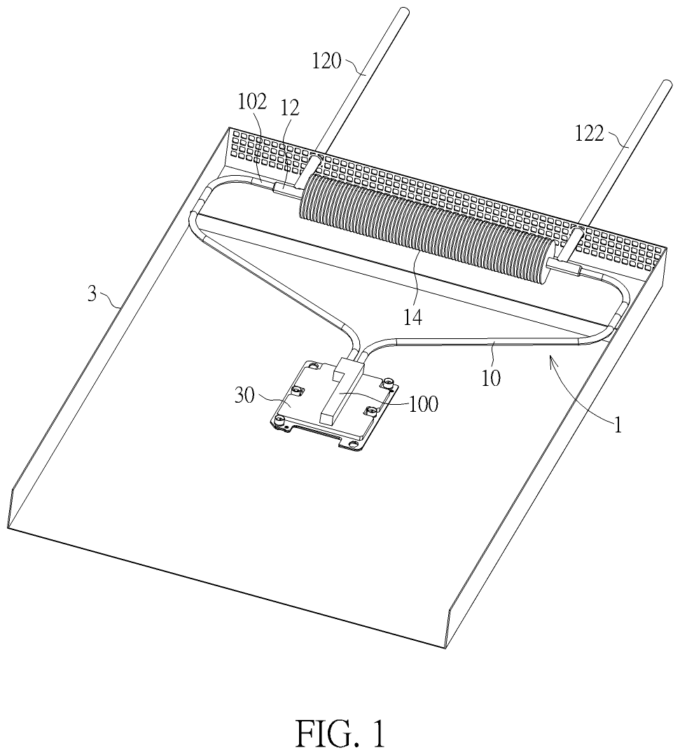

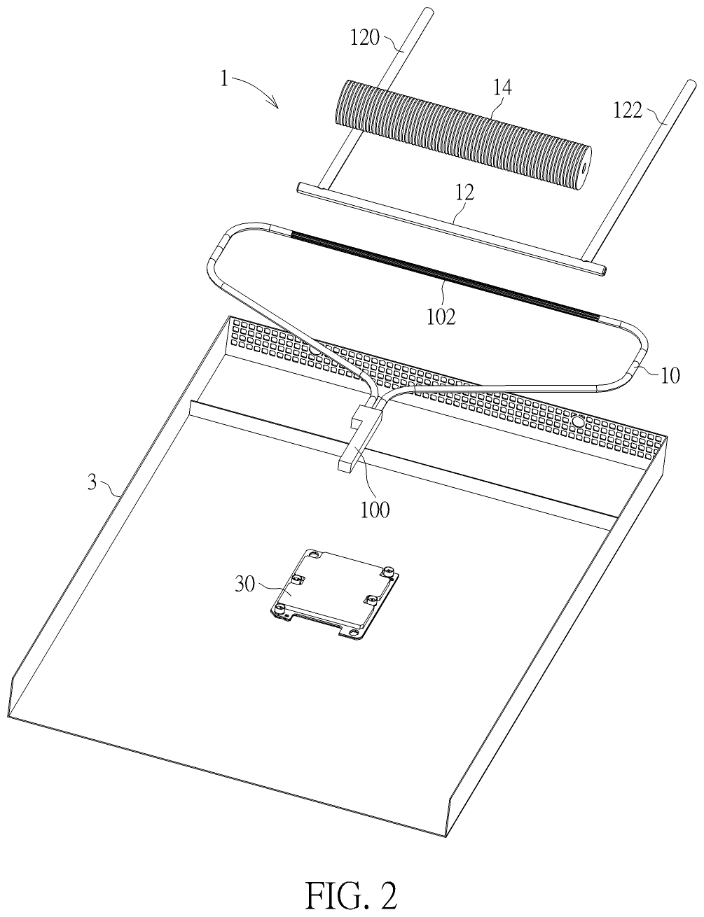

Referring to FIGS. 1 and 2, FIG. 1 is a perspective view illustrating a heat dissipating device 1 according to an embodiment of the invention and FIG. 2 is an exploded view illustrating the heat dissipating device 1 shown in FIG. 1.

As shown in FIGS. 1 and 2, the heat dissipating device 1 comprises a thermosyphon 10, a first liquid cooling tube 12 and a first heat dissipating fin 14. The heat dissipating device 1 may be disposed in a chassis 3 to dissipate heat generated by an electronic component 30 and other electronic components (not shown) in the chassis 3 . The chassis 3 maybe a chassis of a server or other electronic devices, the electronic component 30 maybe a central processing unit, a graphics card or other electronic components, and it depends on practical applications.

The thermosyphon 10 has an evaporation portion 100 and a condensation portion 102. In practical applications, a cooling liquid (e.g. water or other liquids) is filled in the thermosyphon 10. The first liquid cooling tube 12 is sleeved on the condensation portion 102 of the thermosyphon 10. The first liquid cooling tube 12 has a liquid inlet 120 and a liquid outlet 122. The liquid inlet 120 and the liquid outlet 122 may be connected to an external cooling liquid supply device, such that a cooling liquid (e.g. water or other liquids) may flow into the first liquid cooling tube 12 from the liquid inlet 120 and then flow out of the first liquid cooling tube 12 from the liquid outlet 122, so as to form a cooling loop. The first heat dissipating fin set 14 is sleeved on the first liquid cooling tube 12. In this embodiment, the first heat dissipating fin set 14 may be connected to the first liquid cooling tube 12 by a tight-fitting manner or a welding process, but is not so limited. The number of fins of the first heat dissipating fin set 14 may be determined according to practical applications, so the invention is not limited to the embodiment shown in the figures.

As shown in FIG. 1, the evaporation portion 100 of the thermosyphon 10 is in contact with the electronic component 30, so as to dissipate heat from the electronic component 30. The heat generated by the electronic component 30 evaporates the cooling liquid within the thermosyphon 10. Then, the vapor flows to the condensation portion 102 and then is cooled by the cooling liquid within the first liquid cooling tube 12. At the same time, the first heat dissipating fin set 14 absorbs the heat generated by other electronic components inside the chassis 3 and then performs heat exchange with the first liquid cooling tube 12, such that the air will be cooled before flowing out of the chassis 3. Accordingly, the heat dissipating efficiency of the heat dissipating device 1 can be effectively improved.

In this embodiment, a thread structure (e.g. thread groove) may be formed on an inner wall of the first liquid cooling tube 12. Accordingly, the cooling liquid will form a turbulent flow while passing through the thread structure, so as to improve the heat exchange efficiency between the cooling liquid and the outside air.

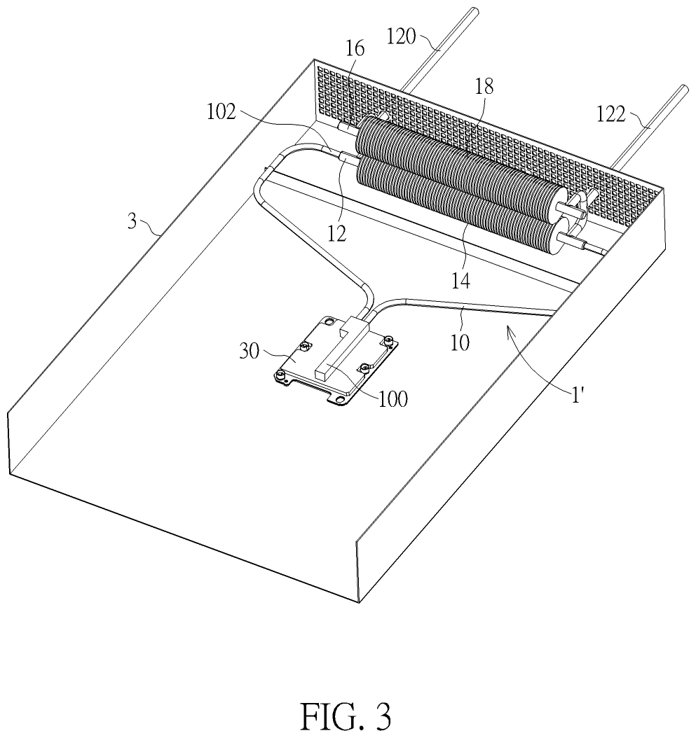

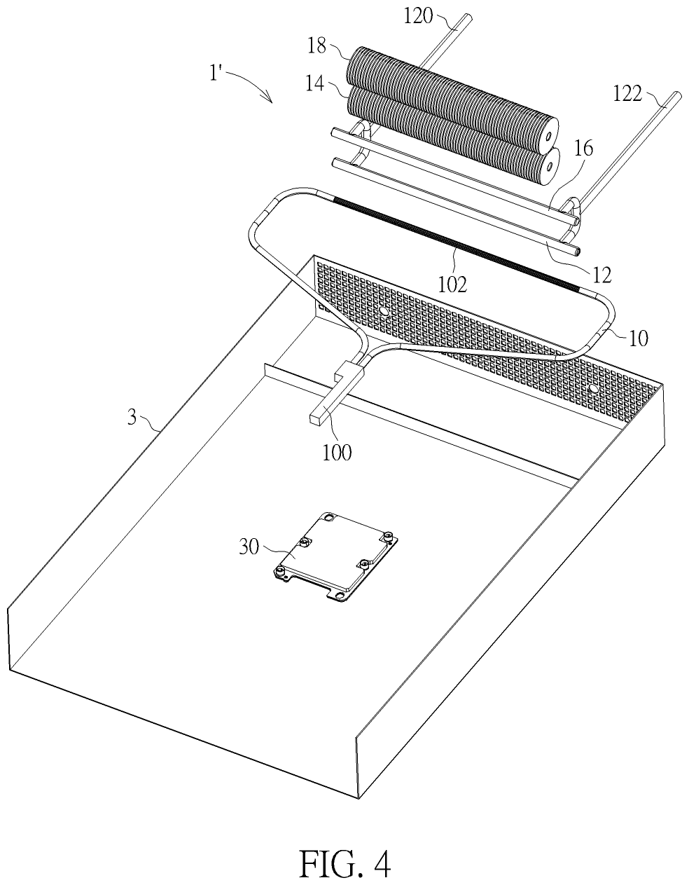

Referring to FIGS. 3 and 4, FIG. 3 is a perspective view illustrating a heat dissipating device 1′ according to another embodiment of the invention and FIG. 4 is an exploded view illustrating the heat dissipating device 1′ shown in FIG. 3. The main difference between the heat dissipating device 1′ and the aforesaid heat dissipating device 1 is that the heat dissipating device 1′ further comprises a second liquid cooling tube 16 and a second heat dissipating fin set 18, as shown in FIGS. 3 and 4. The heat dissipating device 1′ may also be disposed in the chassis 3 to dissipate heat generated by the electronic component 30 and other electronic components (not shown) in the chassis 3.

The second liquid cooling tube 16 and the first liquid cooling tube 12 are connected in parallel, and the second heat dissipating fin set 18 is sleeved on the second liquid cooling tube 16. In this embodiment, the second liquid cooling tube 16 and the first liquid cooling tube 12 share the same liquid inlet 120 and the same liquid outlet 122. Thus, the cooling liquid (e.g. water or other liquids) may also flow into the second liquid cooling tube 16 from the liquid inlet 120 and then flow out of the second liquid cooling tube 16 from the liquid outlet 122, so as to form another cooling loop. Furthermore, the second heat dissipating fin set 18 maybe connected to the second liquid cooling tube 16 by a tight-fitting manner or a welding process, but is not so limited. The number of fins of the second heat dissipating fin set 18 may be determined according to practical applications, so the invention is not limited to the embodiment shown in the figures.

In this embodiment, the second heat dissipating fin set 18 may be used to absorb the heat generated by other electronic components inside the chassis 3 and then perform heat exchange with the second liquid cooling tube 16, such that the air will be cooled before flowing out of the chassis 3. Accordingly, the heat exchange efficiency between the cooling liquid and the outside air can be further effectively improved.

In this embodiment, a thread structure (e.g. thread groove) may be formed on an inner wall of the second liquid cooling tube 16. Accordingly, the cooling liquid will form a turbulent flow while passing through the thread structure, so as to improve the heat exchange efficiency between the cooling liquid and the outside air.

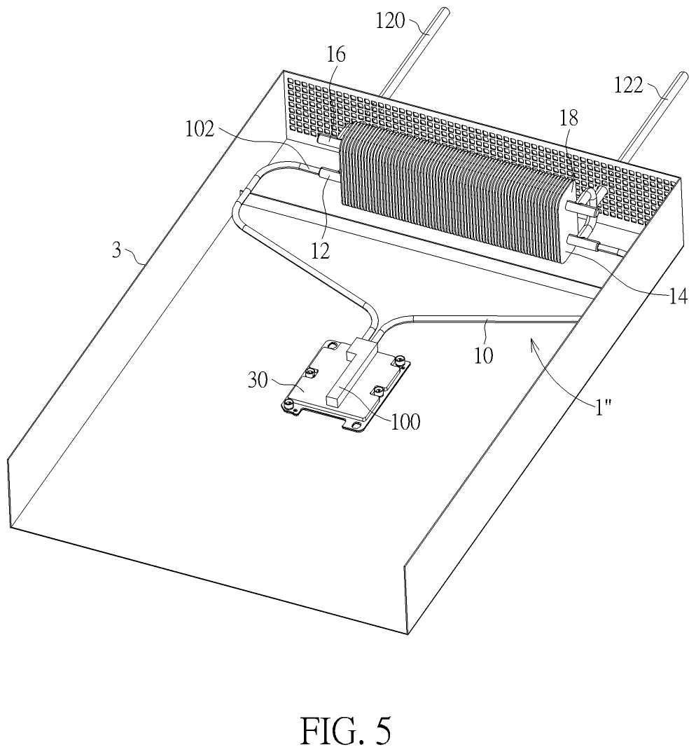

Referring to FIG. 5, FIG. 5 is a perspective view illustrating a heat dissipating device 1″ according to another embodiment of the invention. The main difference between the heat dissipating device 1″ and the aforesaid heat dissipating device 1′ is that the first heat dissipating fin set 14 and the second heat dissipating fin set 18 of the heat dissipating device 1″ are formed integrally, as shown in FIG. 5. The heat dissipating device 1″ may also be disposed in the chassis 3 to dissipate heat generated by the electronic component 30 and other electronic components (not shown) in the chassis 3. Accordingly, the area of the fin can be enlarged in the limited inner space of the chassis 3, so as to improve the heat exchange efficiency.

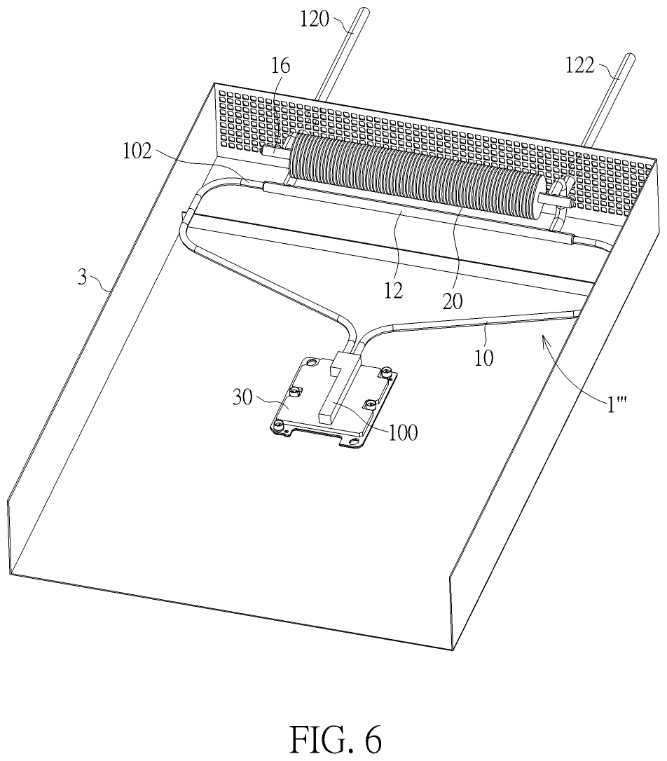

Referring to FIG. 6, FIG. 6 is a perspective view illustrating a heat dissipating device 1′″ according to another embodiment of the invention. As shown in FIG. 6, the heat dissipating device 1′″ comprises a thermosyphon 10, a first liquid cooling tube 12, a second liquid cooling tube 16 and a heat dissipating fin set 20. The heat dissipating device 1′″ may also be disposed in the chassis 3 to dissipate heat generated by the electronic component 30 and other electronic components (not shown) in the chassis 3. The structure and principle of the thermosyphon 10, the first liquid cooling tube 12 and the second liquid cooling tube 16 are mentioned in the above and those will not be depicted herein again.

In this embodiment, the heat dissipating fin set 20 is sleeved on the second liquid cooling tube 16. The heat dissipating fin set 20 may be connected to the second liquid cooling tube 16 by a tight-fitting manner or a welding process, but is not so limited. The number of fins of the heat dissipating fin set 20 maybe determined according to practical applications, so the invention is not limited to the embodiment shown in the figures. In this embodiment, the heat dissipating fin set 20 may be used to absorb the heat generated by other electronic components inside the chassis 3 and then perform heat exchange with the second liquid cooling tube 16, such that the air will be cooled before flowing out of the chassis 3. Accordingly, the heat exchange efficiency between the cooling liquid and the outside air can be effectively improved. Therefore, when the second liquid cooling tube 16 and the first liquid cooling tube 12 are connected in parallel, there may be no heat dissipating fin set disposed on the first liquid cooling tube 12 and it depends on practical applications.

In this embodiment, a thread structure (e.g. thread groove) may be formed on an inner wall of the second liquid cooling tube 16. Accordingly, the cooling liquid will form a turbulent flow while passing through the thread structure, so as to improve the heat exchange efficiency between the cooling liquid and the outside air.

As mentioned in the above, the invention may sleeve the first liquid cooling tube on the condensation portion of the thermosyphon and sleeve the first heat dissipating fin set on the first liquid cooling tube. The evaporation portion of the thermosyphon is in contact with an electronic component. The heat generated by the electronic component evaporates a cooling liquid within the thermosyphon. Then, the vapor flows to the condensation portion and then is cooled by the first liquid cooling tube. At the same time, the first heat dissipating fin set absorbs the heat inside the chassis and then performs heat exchange with the first liquid cooling tube, such that the air will be cooled before flowing out of the chassis. Accordingly, the heat dissipating efficiency of the heat dissipating device can be effectively improved. Furthermore, the invention may add the second liquid cooling tube and the second heat dissipating fin set to further improve the heat exchange efficiency. In another embodiment, the invention may utilize the first liquid cooling tube to cool the condensation portion of the thermosyphon and utilize the second liquid cooling tube and the heat dissipating fin set thereon to perform heat exchange for the hot air inside the chassis. In other words, when the second liquid cooling tube and the first liquid cooling tube are connected in parallel, there may be no heat dissipating fin set disposed on the first liquid cooling tube and it depends on practical applications.

In an embodiment of the invention, the heat dissipating device of the invention may be applied to a server, wherein the server may not only be applied to artificial intelligence (AI) and edge computing, but also be used as a 5G server, a cloud server or an Internet of Vehicles server.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat dissipating device comprising:
a thermosyphon having an evaporation portion and a condensation portion;
a first liquid cooling tube sleeved on the condensation portion; and
a first heat dissipating fin set sleeved on the first liquid cooling tube.

2. The heat dissipating device of claim 1, wherein a thread structure is formed on an inner wall of the first liquid cooling tube.

3. The heat dissipating device of claim 1, wherein the first heat dissipating fin set is connected to the first liquid cooling tube by a tight-fitting manner or a welding process.

4. The heat dissipating device of claim 1, further comprising a second liquid cooling tube and a second heat dissipating fin set, the second liquid cooling tube and the first liquid cooling tube being connected in parallel, the second heat dissipating fin set being sleeved on the second liquid cooling tube.

5. The heat dissipating device of claim 4, wherein the first heat dissipating fin set and the second heat dissipating fin set are formed integrally.

6. The heat dissipating device of claim 4, wherein a thread structure is formed on an inner wall of the second liquid cooling tube.

7. The heat dissipating device of claim 4, wherein the second heat dissipating fin set is connected to the second liquid cooling tube by a tight-fitting manner or a welding process.

8. A heat dissipating device comprising:
a thermosyphon having an evaporation portion and a condensation portion;
a first liquid cooling tube sleeved on the condensation portion;
a second liquid cooling tube, the second liquid cooling tube and the first liquid cooling tube being connected in parallel; and
a heat dissipating fin set sleeved on the second liquid cooling tube.

9. The heat dissipating device of claim 8, wherein a thread structure is formed on an inner wall of the second liquid cooling tube.

10. The heat dissipating device of claim 8, wherein the heat dissipating fin set is connected to the second liquid cooling tube by a tight-fitting manner or a welding process.
